(19) United States
(12) Patent Application Publication
(10) Pub. No.: US 2025/0063775 A1
(43) Pub. Date: Feb. 20, 2025

(54) SEMICONDUCTOR DEVICE HAVING A SUPERJUNCTION-STRUCTURE

(71) Applicant: Infineon Technologies AG, Neubiberg (DE)

(72) Inventors: Michael Hell, Erlangen (DE); Caspar Leendertz, München (DE); Rudolf Elpelt, Erlangen (DE); Björn Fischer, München (DE)

(21) Appl. No.: 18/794,077

(22) Filed: Aug. 5, 2024

(30) Foreign Application Priority Data
Aug. 17, 2023 (DE) 102023122081.0

(51) Int. Cl. H01L 29/06; H01L 21/04; H01L 29/16; H01L 29/66; H01L 29/78

(52) U.S. Cl. CPC H01L 29/0634; H01L 21/047; H01L 29/1608; H01L 29/66068; H01L 29/7813

(57) ABSTRACT

A semiconductor device includes a transistor having a plurality of gate trenches formed in a semiconductor substrate, the gate trenches patterning the semiconductor substrate into ridges. The transistor further includes a gate electrode arranged in at least one of the gate trenches. A source region, a channel region and a part of a current spread region are arranged in the ridges. The semiconductor device further includes a superjunction structure arranged at a larger distance to the source region than the channel region. The superjunction structure includes a first compensation region of the first conductivity type and a second compensation region of the second conductivity type. A doping concentration of the doped portion of the second conductivity type of the channel region decreases in a second horizontal direction intersecting the first horizontal direction from a region close to the gate electrode to a central portion of the ridge.

### TECHNICAL FIELD

Examples of the present disclosure relate to semiconductor devices, in particular, to semiconductor devices comprising a transistor including a superjunction-structure.

### BACKGROUND

Transistors, in which a gate electrode is arranged in trenches adjacent to a channel region are widely used. Attempts are being made to further improve characteristics of these transistors.

The present disclosure is directed to a semiconductor device comprising an improved transistor which may be beneficially applied e.g. to a silicon carbide substrate.

### SUMMARY

According to an example, a semiconductor device comprises a transistor. The transistor comprises a plurality of gate trenches formed in a semiconductor substrate. The gate trenches pattern the semiconductor substrate into ridges extending in a first horizontal direction. The ridges are arranged between two adjacent gate trenches, respectively. The transistor further comprises a gate electrode arranged in at least one of the gate trenches. The transistor further comprises a source region of a first conductivity type and electrically coupled to a source terminal, a channel region comprising a doped portion of a second conductivity type, a current spread region of the first conductivity type, and a drain region electrically coupled to a drain terminal. The source region, the channel region and a part of the current spread region are arranged in the ridges. The gate electrode is insulated from the channel region and the current spread region, wherein a width of the source region corresponds to a width of the ridge. The semiconductor device further comprises a superjunction structure arranged at a larger distance to the source region than the channel region. The superjunction structure comprises a first compensation region of the first conductivity type, the first compensation region being electrically coupled to the drain terminal. The superjunction structure further comprises a second compensation region of the second conductivity type, the second compensation region being electrically coupled to the doped portion of the second conductivity type of the channel region. The first and the second compensation regions are adjacent to each other. A doping concentration of the doped portion of the second conductivity type of the channel region decreases in a second horizontal direction intersecting the first horizontal direction from a region close to the gate electrode to a central portion of the ridge.

According to further examples, a semiconductor device comprises a transistor. The transistor comprises a plurality of gate trenches formed in a SiC substrate. The gate trenches pattern the semiconductor substrate into ridges extending in a first horizontal direction, the ridges being arranged between two adjacent gate trenches, respectively. The transistor further comprises a gate electrode arranged in at least one of the gate trenches. The transistor further comprises a source region of a first conductivity type and electrically coupled to a source terminal, a channel region comprising a doped portion of a second conductivity type, a current spread region of the first conductivity type, and a drain region electrically coupled to a drain terminal. The source region, the channel region and a part of the current spread region are arranged in the ridges. The gate electrode is insulated from the channel region and the current spread region. A width of the source region corresponds to a width of the ridge. The semiconductor device further comprises a superjunction structure arranged at a larger distance to the source region than the channel region. The superjunction structure comprises a first compensation region of the first conductivity type, the first compensation region being electrically coupled to the drain terminal. The superjunction structure further comprises a second compensation region of the second conductivity type. The second compensation region is electrically coupled to the doped portion of the second conductivity type of the channel region, the first and the second compensation regions being adjacent to each other.

### BRIEF DESCRIPTION OF THE DRAWINGS

The accompanying drawings are included to provide a further understanding of the embodiments and are incorporated in and constitute a part of this specification. The drawings together with the description serve to explain principles of the embodiments. Further embodiments are described in the following detailed description and the claims.

FIG. 1A shows an example of a vertical cross-sectional view of a portion of a semiconductor device according to examples.

FIG. 1B shows a vertical cross-sectional view of a portion of a semiconductor device according to further examples.

FIG. 2A shows a horizontal cross-sectional view of a semiconductor device according to examples.

FIG. 2B shows vertical sectional views of a portion of a semiconductor device according to examples.

FIG. 2C shows vertical cross-sectional views of a portion of the semiconductor device according to further examples.

FIG. 3A shows a horizontal cross-sectional view of a semiconductor device according to further examples.

FIG. 3B is a vertical cross-sectional view of a portion of the semiconductor device according to examples.

FIG. 3C shows an example of a doping concentration in the channel region.

FIG. 4A shows a horizontal cross-sectional view of a portion of a semiconductor device according to examples.

FIG. 4B shows vertical cross-sectional views of a portion of the semiconductor device at different locations.

FIG. 5A shows a horizontal cross-sectional view of a semiconductor device according to further examples.

FIGS. 5B and 5C show vertical cross-sectional views of the semiconductor device at different locations.

FIG. 5D shows a further horizontal cross-sectional view of the semiconductor device.

FIGS. 5E and 5F show vertical cross-sectional views of a further semiconductor device at different locations.

FIG. 5G shows a further horizontal cross-sectional view of the semiconductor device.

FIG. 6A shows a horizontal cross-sectional view of a semiconductor device according to further examples.

FIG. 6B shows a vertical cross-sectional view of the semiconductor device.

FIG. 6C shows a further horizontal cross-sectional view of the semiconductor device.

FIGS. 6D and 6E show vertical cross-sectional views of a semiconductor device according to further examples at different locations.

FIG. 6F shows a further horizontal cross-sectional view of the semiconductor device.

FIG. 7A shows a horizontal cross-sectional view of a semiconductor device according to further examples.

FIGS. 7B and 7C show vertical cross-sectional views of the semiconductor device along a second direction at different locations.

FIGS. 7D and 7E show vertical cross-sectional views of the semiconductor device along a first direction at different locations.

FIG. 7F shows a further horizontal cross-sectional view of the semiconductor device.

FIG. 8A shows a horizontal cross-sectional view of a portion of a semiconductor device according to further examples.

FIGS. 8B and 8C show vertical cross-sectional views of the semiconductor device along a second direction at different locations.

FIGS. 8D and 8E show vertical cross-sectional views of the semiconductor device along a first direction at different locations.

FIGS. 9A to 9H show cross-sectional views of a workpiece when performing a method of manufacturing a semiconductor device according to examples.

FIGS. 91 and 9J show cross-sectional views of a workpiece when performing a method according to a modification.

FIGS. 10A to 10H show cross-sectional views of a workpiece when performing a method of manufacturing a semiconductor device according to examples.

FIGS. 11A to 11H show cross-sectional views of a workpiece when performing a method according to further examples.

### DETAILED DESCRIPTION

In the following detailed description, reference is made to the accompanying drawings, which form a part hereof and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language, which should not be construed as limiting the scope of the appending claims. The drawings are not scaled and are for illustrative purposes only. For clarity, the same elements have been designated by corresponding references in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

Ranges given for physical dimensions include the boundary values. For example, a range for a parameter y from a to b reads as a≤y≤b. A parameter y with a value of at least c reads as c≤y and a parameter y with a value of at most d reads as y≤d.

The term “on” is not to be construed as meaning only “directly on”. Rather, if one element is positioned “on” another element (e.g., a layer is “on” another layer or “on” a substrate or semiconductor body), a further component (e.g., a further layer) may be positioned between the two elements (e.g., a further layer may be positioned between a layer and a substrate if the layer is “on” said substrate).

Throughout the present specification elements of transistor cells of a field effect transistor are described. Generally, the field effect transistor may comprise a plurality of transistor cells that are connected in parallel. For example, each single transistor cell may comprise a single gate electrode, a single channel region and further components. The gate electrodes of the single transistor cells may be connected, e.g. electrically connected and/or formed of the same materials. For example, the gate electrodes of the single transistor cells may be connected to a common terminal, e.g. a gate terminal. Further components of the single transistor cells, e.g. the source regions may be respectively connected to a common source terminal. Still further components of the single transistor cells, e.g. the current spread region or the drift region, may be shared among at least some of the transistor cells. The present specification mainly describes the function and structure of the single transistor cells. As is to be readily understood, this description may likewise apply to the further single transistor cells. Descriptions merging the general elements of the transistor and the structural implementation by means of elements of the single transistor cells such as “a gate electrode arranged in gate trenches” are intended to mean that single gate electrodes of respective transistor cells are arranged in respective gate trenches.

An example of a semiconductor device comprises a transistor. The transistor may comprise a plurality of gate trenches formed in a semiconductor substrate. The gate trenches may pattern the semiconductor substrate into ridges extending in a first horizontal direction. The ridges may be arranged between two adjacent gate trenches, respectively. The transistor may further comprise a gate electrode which is arranged in at least one of the gate trenches.

The transistor may further comprise a source region of a first conductivity type and electrically coupled to a source terminal. The transistor may further comprise a channel region comprising a doped portion of a second conductivity type, and a current spread region of the first conductivity type. The source region, the channel region and a part of the current spread region are arranged in the ridges. The transistor may further comprise a drain region that is electrically coupled to a drain terminal.

The gate electrode may be insulated from the channel region and the current spread region. The source region may be arranged at least in a central portion of the ridge. The term “central portion” may refer to a central portion with respect to a second horizontal direction perpendicular to the first horizontal direction. Accordingly, the source region may be arranged in a portion of the ridge having approximately equal distances to a first side face and a second side face of the ridge, respectively. According to further embodiments, the arrangement of the source region does not need to be symmetrical with respect to the second horizontal direction. The term “source region arranged at least in a central portion of the ridge” is intended to refer to an arrangement according to which doped portions of the second conductivity type may be arranged in a horizontal edge portion of the ridge, e.g. adjacent to at least one of the side faces of the ridge.

The semiconductor device may further comprise a superjunction structure arranged at a larger distance to the source region than the channel region. The superjunction structure may comprise a first compensation region of the first conductivity type and a second compensation region of the second conductivity type. The first compensation region may be electrically coupled to the drain terminal. The second compensation region may be electrically coupled to the doped portion of the second conductivity type of the channel region. The first and the second compensation regions may be arranged adjacent to each other.

A doping concentration of the doped portion of the second conductivity type of the channel region may decrease in a second horizontal direction intersecting the first horizontal direction from a region close to the gate electrode to a central portion of the ridge. For example, the channel region may comprise a doped portion of the first conductivity type in the central portion of the ridge.

When a suitable voltage is applied to the gate electrode, a conductive channel is formed in the channel region. As a consequence, a current path having a vertical component is formed between the source region, the channel region, the current spread region, and the drain region. The current path from the source region to the current-spreading region may extend in a depth direction of the silicon carbide substrate. For example, the depth direction may correspond to a vertical direction e.g. the z-direction. According to further embodiments, the depth direction may be a direction different from the vertical direction. Generally, the depth direction is a direction different from a lateral or horizontal direction. For example, the depth direction may have a component which is perpendicular to the lateral direction or to a main surface of the silicon carbide substrate. For example, the depth direction may be slanted with respect to the vertical direction.

The term “ridge” as employed within this disclosure is intended to mean a structure, e.g. a mesa, comprising two sidewalls and a top portion between the sidewalls. The sidewalls extend in a depth direction. For example, the sidewalls may be slanted with respect to a vertical direction. According to further interpretations, the term “ridge” may also be understood to implement a “fin”. Since the channel of the transistor is arranged within the ridge, the transistor is also referred to as a “FinFET”.

Transistors described herein may specifically include IGFETs (“insulated gate field effect transistor”). IGFETs are voltage controlled devices including MOSFETs (“metal oxide semiconductor FETs”) and other FETs comprising gate electrodes based on doped semiconductor material and/or comprising gate dielectrics that are not exclusively based on an oxide. As is to be clearly understood, further transistors may relate to IGBTs (“insulated gate bipolar transistor”).

According to implementations, a width of the source region may correspond to a width of the ridge. Accordingly, the source region may extend from one side face of the ridge to another side face of the ridge. Differently stated, it is possible that a further trench or a doped portion of another conductivity type is not present within the source region.

For example, the doped portion of the second conductivity type of the channel region may be electrically connected to the source terminal via a body contact portion.

For example, the second compensation region may be electrically coupled to the source terminal. For example, the second compensation region may be electrically coupled to the doped portion of the second conductivity type of the channel region. Accordingly, the second compensation region may be electrically coupled to the source terminal via the channel region.

The superjunction structure allows for a reduced resistance of the drift zone while maintaining the breakdown voltage V_{br} in comparison with a drift zone of the first conductivity type without a superjunction structure. A lateral width of the first and second compensation regions may be smaller than an extension of the first and the second compensation regions in the depth direction.

The gate electrode may be insulated from the channel region and the current spread region. For example, the gate electrode may be insulated from the channel region and the current-spreading region by means of a gate dielectric such as e.g. silicon oxide, silicon nitride or a combination of these materials. According to further examples, any other dielectric material, e.g. a high-k dielectric may be used.

In summary, the semiconductor device combines a FinFET structure with a superjunction structure. Due to the FinFET structure a channel resistance may be reduced. Due to the superjunction structure a resistance in the drift region may be reduced. As a result, a power transistor with low on-state losses may be implemented.

For example, the channel region may comprise a doped portion of the first conductivity type in the central portion of the ridge. In this case, the first compensation region may be electrically coupled to the doped portion of the first conductivity type.

Further, the second compensation region may be electrically coupled to the source terminal via a body contact portion that electrically couples the doped portion of the second conductivity type of the channel region to the source terminal.

By way of example, the semiconductor device may further comprise a shielding portion of the second conductivity type that is arranged below the gate trenches, respectively. For example, the shielding portion may be doped at a higher doping concentration than the second compensation region. The second compensation region may be electrically coupled to the shielding portion.

The shielding portion may contribute to shielding a gate dielectric against an electric potential that may be applied at the back side of the silicon carbide body. In a blocking mode of the silicon carbide device, the shielding portion may reduce the electric field in the gate dielectric and may thus contribute to increasing device reliability. For example the shielding portion may be doped at a higher doping level than the doped portion of the second conductivity type of the channel region. The shielding portion may be in contact with the current spread region. The shielding portion may be in contact with a source metallization layer that is electrically coupled to the source terminal.

According to examples, the superjunction structure may extend in the first horizontal direction.

According to further examples, the superjunction structure may extend in a second horizontal direction intersecting the first horizontal direction.

According to examples, the source region may continuously extend along the first horizontal direction in the ridges.

According to further examples, the source region may be segmented into source region segments along the first horizontal direction. The transistor may further comprise body contact portions which are arranged between adjacent source region segments.

According to examples, the transistor may further comprise a drift region of the first conductivity type arranged between the superjunction structure and the drain region.

By way of example, the gate trenches may continuously extend in the first horizontal direction.

The semiconductor device may further comprise contact grooves running in the first horizontal direction. The contact grooves may extend through the gate trenches in a depth direction. A metal layer arranged in the contact grooves may be electrically coupled to the source terminal. The metal layer may be further electrically coupled to the second compensation region of the second conductivity type. The contact grooves may further or alternatively be in contact with the shielding portions. In this manner, the shielding portions may be electrically coupled to the source terminal. Further or alternatively, the metal layer in the contact groove may be in contact with the body contact portion. For example, the metal layer in the contact grooves may be disconnected from a portion of the first conductivity type so as to avoid a direct, non-controllable current path between source and drain regions.

For example, the contact grooves may continuously extend in the first horizontal direction. According to further examples, the contact grooves may be segmented to contact groove islands. In this case, the gate electrode may be present between adjacent contact groove islands.

According to further examples, the gate trenches may be segmented into a plurality of trench segments which are arranged along the first horizontal direction.

For example, the semiconductor device may further comprise a metal layer that is electrically coupled to the source terminal. The metal layer may be arranged in contact with the source region between adjacent trench segments. For example, in this manner the source regions and the doped portion of the second conductivity type of the channel region may be electrically coupled to the source terminal.

According to further examples, a semiconductor device may comprise a transistor. The transistor may comprise a plurality of gate trenches formed in a SiC substrate. The gate trenches may pattern the semiconductor substrate into ridges which extend in a first horizontal direction. The ridges may be arranged between two adjacent gate trenches, respectively. The transistor may further comprise a gate electrode arranged in at least one of the gate trenches and a source region of a first conductivity type and electrically coupled to a source terminal. The transistor may further comprise a channel region comprising a doped portion of a second conductivity type, a current spread region of the first conductivity type, and a drain region electrically coupled to a drain terminal. The source region, the channel region and a part of the current spread region may be arranged in the ridges. The gate electrode may be insulated from the channel region and the current spread region. A width of the source region may correspond to a width of the ridge.

The semiconductor device may further comprise a superjunction structure arranged at a larger distance to the source region than the channel region. The superjunction structure may comprise a first compensation region of the first conductivity type which is electrically coupled to the drain terminal and a second compensation region of the second conductivity type. The second compensation region may be electrically coupled to the doped portion of the second conductivity type of the channel region. The first and the second compensation regions may be arranged adjacent to each other.

For example the first compensation region may be electrically coupled to the current spread region.

By way of example, a doping concentration of the doped portion of the second conductivity type of the channel region may decrease in a second horizontal direction intersecting the first horizontal direction from a region close to the gate electrode to a central portion of the ridge.

For example, the channel region may further comprise a doped portion of the first conductivity type in the central portion of the ridge. The first compensation region may be electrically coupled to the doped portion of the first conductivity type in the central portion of the ridge.

As described herein, the semiconductor substrate may be a silicon carbide (SiC) substrate. According to an example, the silicon carbide substrate may have a hexagonal crystal lattice with a c-plane and further main planes. The further main planes may include a-planes or m-planes.

The c-plane is a {0001}lattice plane. The further main planes may include a-planes ({11-20}family of lattice planes) and m-planes ({1-100}family of lattice planes). The a-planes include the six differently oriented lattice planes (11-20), (1-210), (−2110), (−1-120), (−12-10), and (2-1-10). The m-planes include the six differently oriented lattice planes (1-100), (10-10), (01-10), (−1100), (−1010), and (0-110).

The mean surface plane of the silicon carbide substrate may be tilted to the c-plane by an off-axis angle. In other words, the c-axis may be tilted to the vertical direction by the off-axis angle. The off-axis angle may be in a range from 2 degrees to 8 degrees, for example in a range from 3 degrees to 5 degrees. In particular, the off-axis angle may be approximately 4 degrees. For example, the c-axis may be tilted such that a plane spanned by the vertical direction and the c-axis is parallel to a {11-20}>plane. According to another example, the c-axis may be tilted such that a plane spanned by the vertical direction and the c-axis is parallel to a {1-100}plane. At the back side of the silicon carbide substrate, a second main surface of the silicon carbide substrate may extend parallel or approximately parallel to the mean surface plane at the front side.

A first main surface at a front side of the silicon carbide substrate may be planar or ribbed. A mean surface plane of the first main surface extends along the horizontal directions. The mean surface plane of a planar first main surface is identical with the planar first main surface. The mean surface plane of a ribbed first main surface is defined by the planar least squares plane of the ribbed first main surface. Position and orientation of the planar least squares plane are defined such that the sum of the squares of the deviations of surface points of the ribbed first main surface from the planar least squares plane has a minimum.

The silicon carbide substrate may horizontally extend along a plane spanned by the horizontal directions. Accordingly, the silicon carbide body may have a surface extension along two horizontal directions and may have a thickness along a vertical direction perpendicular to the horizontal directions. In other words, the vertical direction is parallel to a surface normal onto the mean surface plane.

The gate trenches may pattern the first portion of the silicon carbide substrate into ridges. By way of example, at least one of the sidewalls of the gate trenches and the ridges may be parallel to the (1-100) or the (−1100) planes.

The terms “first horizontal direction” and “second horizontal direction” define intersecting horizontal directions. Although some of the figures show—by way of illustration—the x-direction and the y-direction as examples of the first and the second horizontal directions, it is clearly to be understood, that the first horizontal direction and the second horizontal direction do not need to be perpendicular to each other. The term “depth direction” defines a direction having a component perpendicular to the mean surface plane. The term “depth direction” encompasses the vertical direction and any other direction different from a horizontal direction.

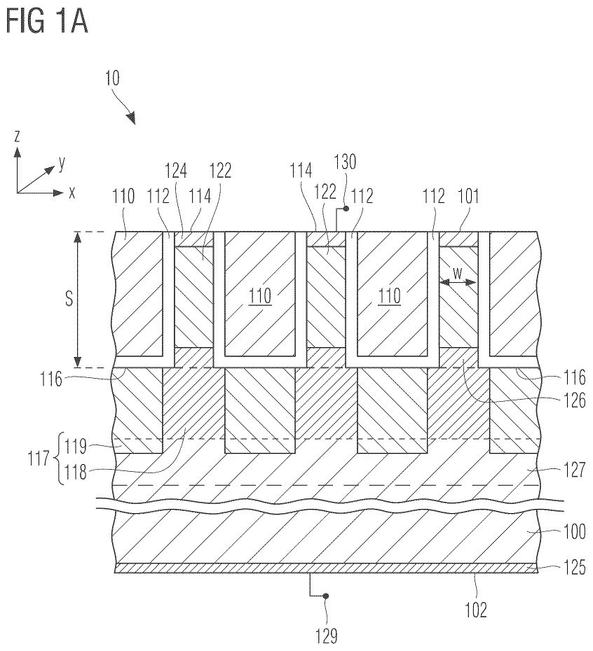

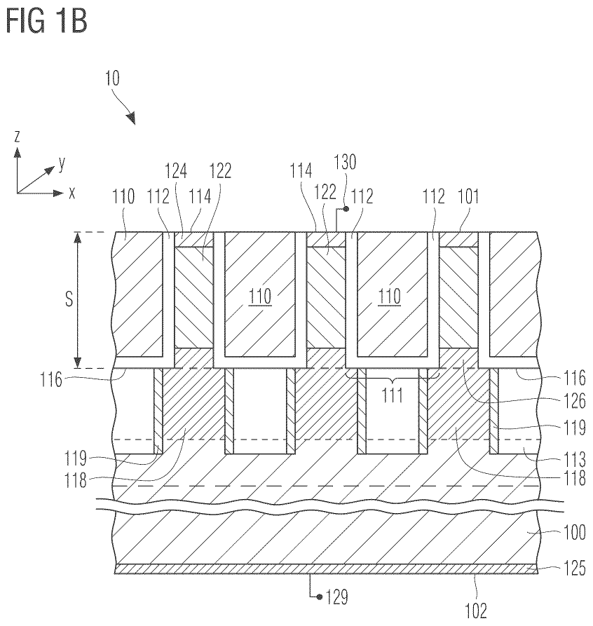

FIG. 1A shows a vertical cross-sectional view of a semiconductor device 10 according to examples. The semiconductor device 10 comprises a transistor. The transistor comprises a plurality of gate trenches 111 that are formed in a semiconductor substrate 100, e.g. a SiC substrate. The gate trenches 111 pattern the semiconductor device substrate 100 into ridges 114 extend in a first horizontal direction, e.g. the y-direction. The ridges 114 are arranged between two adjacent gate trenches 111, respectively. The transistor further comprises a gate electrode 110 that is arranged in at least one of the gate trenches 111. The semiconductor device 10 further comprises a source region 124 of a first conductivity type, e.g. n-type which is electrically coupled to a source terminal 130. The transistor further comprises a channel region 122 comprising a doped portion of a second conductivity type, e.g. p-type, a current spread region 126 of the first conductivity type, and a drain region 125 electrically coupled to a drain terminal 129.

The source region 124, the channel region 122 and a part of the current spread region 126 are arranged in the ridges 114. The gate electrode 110 is insulated from the channel region 122 and the current spread region 126. The source region 124 is arranged in a central portion of the ridge 114. A width w of the source region 124 may correspond to a width of the ridge 114. The channel portion 122 may be electrically coupled to the source terminal 130.

The semiconductor device further comprises a superjunction structure 117 that is arranged at a larger distance to the source region 124 than the channel region 122. The superjunction structure 117 comprises a first compensation region 118 of the first conductivity type. The first compensation region 118 is electrically coupled to the drain terminal 129. The superjunction structure further comprises a second compensation region 119 of the second conductivity type. The second compensation region 119 is electrically coupled to the doped portion of the second conductivity type of the channel region 122. Further, the second compensation region 119 may be electrically coupled to the source terminal 130 via a body contact portion 123. The first and the second compensation regions 118, 119 are arranged adjacent to each other. The superjunction structure is arranged at a larger depth within the semiconductor substrate than the source region and the channel region.

As is shown in FIG. 1A, the first compensation region 118 and the second compensation region 119 are alternatingly arranged below an area in which the gate trenches 111 are formed. A sequence of the arrangement of first and second compensation regions 118, 119 may be continuous.

FIG. 1B shows a vertical cross-sectional view of a semiconductor device 10 according to further examples. The semiconductor device 10 comprises similar or identical components as the semiconductor device 10 illustrated in FIG. 1A. Differing from examples illustrated in FIG. 1A, extended trench portions 113 are arranged below the gate trenches 111. In more detail, the superjunction structure 117 of the semiconductor device 10 shown in FIG. 1B comprises a first compensation region 118 of the first conductivity type in a similar manner as has been explained with reference to FIG. 1A. The second compensation region 119 of the second conductivity type is implemented by a doped sidewall portion at the extended trench portion 113. This specific arrangement of the superjunction structure 117 may be due to a manufacturing process which comprises a tilted ion implantation process. During this process, a portion of the trench is maintained after performing the ion implantation process. When the extended trench portion 113 is fully embedded in doped material of the second conductivity type, the gate dielectric 112 may be effectively shielded in some examples. In other examples, it is possible that the gate dielectric 112 is not effectively shielded. Further, current spread losses may be reduced.

According to examples illustrated in FIGS. 1A and 1B, the first compensation region 118 may be arranged below the ridges 114. Further, for example, the second compensation regions 119 may be arranged below the gate trenches 111.

As is illustrated in FIG. 1A, the semiconductor device may further comprise a drift region 127 of the first conductivity type which is arranged between the superjunction structure 117 and the drain region 125. The drift region 127 may be arranged between the drain region 125 and current spread region 126.

According to examples, the channel region 122 may be doped with a constant doping profile. According to further examples, a doping concentration of the second conductivity type may decrease from an edge portion of the channel region 122 to a central portion thereof in a horizontal direction. According to further implementations, the channel region 122 may comprise a doped portion of the first conductivity type in a central portion thereof. This will be explained in more detail below.

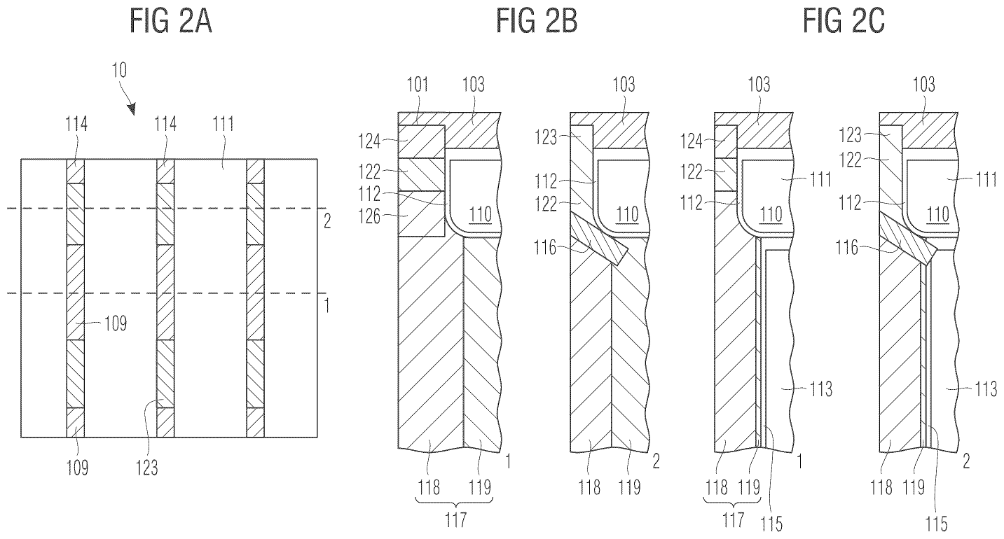

FIG. 2A shows a horizontal cross-sectional view of a semiconductor device 10 according to further examples. As is shown, the semiconductor substrate is patterned into ridges 114 by gate trenches 111. For example, a width of the gate trenches 111 measured in a second horizontal direction may be much larger than a width of the ridges 114 measured in the second horizontal direction. For example, the width of the gate trenches 111 may be larger than 3*(the width of the ridges 114). Moreover, the source region 124 may be segmented into source region segments 109 along the first horizontal direction. The semiconductor device 10 may further comprise body contact portions 123 between adjacent source region segments 109 along the first horizontal direction.

FIG. 2B shows cross-sectional views of the semiconductor device when the superjunction structure 117 is implemented in a manner similar to the implementation illustrated in FIG. 1A. In more detail, the first and the second compensation regions 118, 119 continuously alternate along the second direction. The left-hand portion of FIG. 2B shows a cross-sectional view taken at location 1 so as to intersect the source region segment 109. The right-hand portion of FIG. 2B is taken at position 2 so as to intersect the body contact portion 123.

FIG. 2B shows a portion of the gate trench 111. A gate electrode 110 is arranged in the gate trench. The gate electrode may be insulated from the further elements of the transistor by means of a gate dielectric 112. The first compensation region 118 and the second compensation region 119 extend in a depth direction, e.g. the z-direction or another direction having a component in the z-direction and are sequentially arranged along the second direction. As is shown in the left-hand portion of FIG. 2B, the source region 124 is arranged adjacent to a first main surface 101 of the semiconductor substrate 100 and is in direct contact with a source metallization layer 103. The channel region 122 is arranged below the source region 124. A current spread region 126 is arranged below the channel region 122. The first compensation region 118 may be electrically coupled to the current spread region 126. The second compensation region 119 is arranged adjacent to the first compensation region. The superjunction structure 117 comprises a first compensation region 118 and a second compensation region 119.

The right-hand portion of FIG. 2B shows a portion of a cross-sectional view at position 2 intersecting the body contact portion 123. FIG. 2B further shows a shielding portion 116 of the second conductivity type which is arranged adjacent to the channel region 122. The second compensation region 119 may be electrically coupled via the shielding portion 116 to the channel region 122.

The shielding portion may contribute to shielding a gate dielectric against an electric potential that may be applied at the back side of the silicon carbide body. In a blocking mode of the silicon carbide device, the shielding portion may reduce the electric field in the gate dielectric and may thus contribute to increasing device reliability.

FIG. 2C shows an implementation of the semiconductor device 10 when the superjunction structure 117 comprises a sidewall doping of an extended trench portion 113. The left-hand portion of FIG. 2C shows a cross-sectional view intersecting the source region 124. The left-hand portion of FIG. 2C is similar to the structure shown in the left-hand portion in FIG. 2B. Differing from examples illustrated in FIG. 2B, the second compensation region 119 of the second conductivity type is formed as a sidewall doping of the extended trench portion 113.

The right-hand portion of FIG. 2C shows a similar structure as shown in the right-hand portion of FIG. 2B. Differing from examples shown in FIG. 2B, the second compensation region 119 of the second conductivity type is formed as a sidewall doping of the extended trench portion 113. A dielectric layer 115 may be arranged adjacent to the sidewall of the extended trench portion 113. In a similar manner as is shown in the right-hand portion of FIG. 2B, the second compensation region 119 may be electrically coupled to the channel region 122 via a shielding portion 116.

According to implementations, a doping concentration within the channel region 122 may vary along a second horizontal direction from an edge portion of the ridge 114 to a central portion of the ridge 114. For example, the concentration of dopants of the second conductivity type may decrease in a direction to the central portion of the ridge. According to further examples, the channel region 122 may comprise a doped portion 121 of the first conductivity type in the central portion of the ridge.

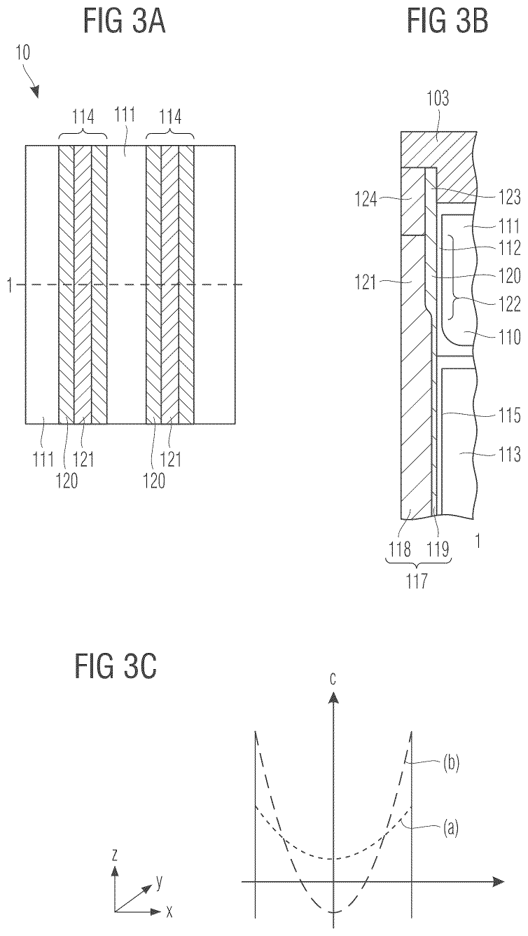

FIG. 3A shows a horizontal cross-sectional view of the semiconductor device 10. As is shown, the semiconductor substrate is patterned into ridges 114 by gate trenches 111. Each of the ridges 114 comprises a doped portion 120 of the second conductivity type at the edge portion and a doped portion 121 of the first conductivity type in the central region. The doped portion 121 of the first conductivity type may continuously extend along the first horizontal direction. Further, the doped portion 120 of the second conductivity type may continuously extend along the first direction.

FIG. 3B shows a vertical cross-sectional view of the semiconductor device. As is shown, the channel region 122 comprises a doped portion 121 of the first conductivity type in the central portion. A source region 124 is arranged over the doped portion 121 of the first conductivity type of the channel region 122. The source region 124 is in direct contact with a source metallization layer 103. Further, a body contact portion 123 is electrically coupled to the doped portion 120 of the second conductivity type of the channel region. The body contact portion 123 may be in direct contact with the source metallization layer.

The superjunction structure 117 comprises a first compensation region 118 of the first conductivity type and a second compensation region 119 of the second conductivity type. The first compensation region 118 may be electrically connected to the doped portion 121 of the first conductivity type. Accordingly, due to the presence of the doped portion 121 of the first conductivity type, an electrical contact may be easily accomplished. Further, the mobility of carriers in the channel region may be increased. The large doping at the side face of the channel region 122 may suppress a formation of an inversion layer close to the interface. Instead, an electron accumulation layer may be formed in the doped portion 121 of the first conductivity type of the channel region. In this way, a bulk enhancement may be achieved with wider widths of the mesa or ridge 114 in comparison with a FinFET having a uniform doping of the second conductivity type. The contact elements for contacting the doped portions of the first and the second conductivity type may be arranged one after the other as is also shown in FIG. 3A. As is shown in FIG. 3B, the second compensation region 119 may be implemented as a sidewall doped portion adjacent to an extended trench portion 113. According to further concepts, the superjunction structure 117 may be implemented e.g. in the manner as has been described above with reference to FIGS. 1A and 2B.

FIG. 3C shows a schematic representation of a doping concentration of dopants of the second conductivity type in the channel region 122. As is indicated by curve (a), the doping concentration decreases from an edge portion to a central portion of the ridge 114. The doping concentration of the dopants of the second conductivity type has a positive value. In other words, the channel region 122 does not comprise doped portions of the first conductivity type.

According to curve (b), the doping concentration becomes negative in the central portion. Accordingly, the channel region 122 comprises a doped portion 121 of the first conductivity type.

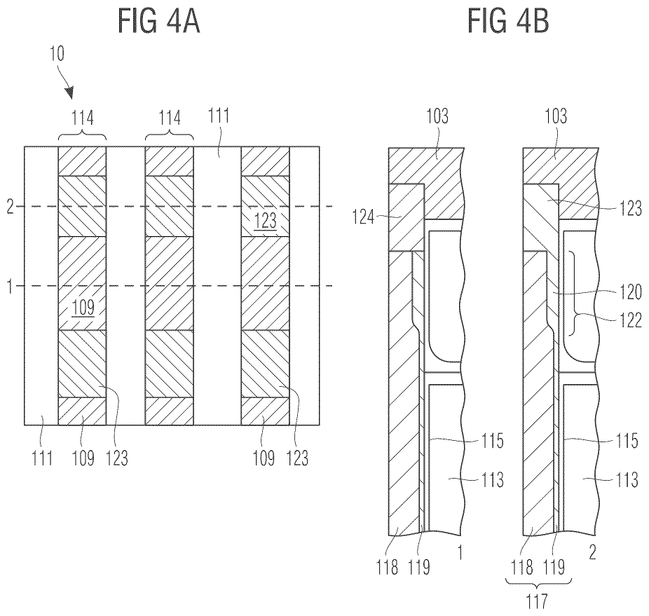

FIG. 4A shows an example of a semiconductor device, in which the source region 124 is segmented into source region segments 109. The source region segments 109 and the body contact portions 123 are alternatingly arranged along the first direction.

FIG. 4B shows vertical cross-sectional views of the semiconductor device. As is shown in the left-hand portion of FIG. 4B, at a position 1, the source region 124 is arranged in direct contact with a source metallization layer 103. The source metallization layer 103 may be electrically coupled to a source terminal. The right-hand portion of FIG. 4B shows a cross-sectional view comprising the body contact portion 123. The body contact portion 123 is in direct contact with the source metallization 103. Further components of the semiconductor device are similar or identical with those explained in FIG. 3B.

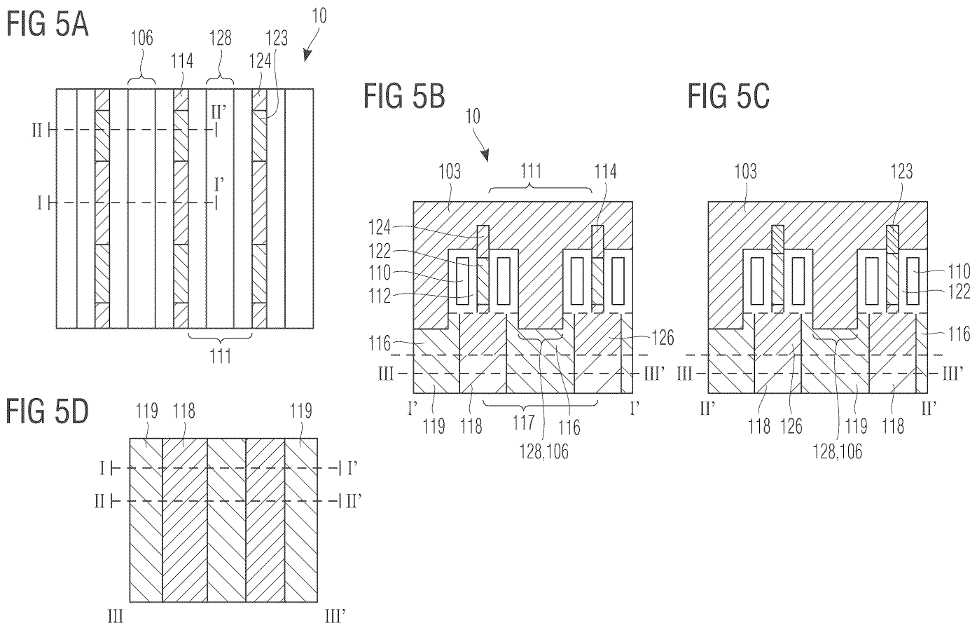

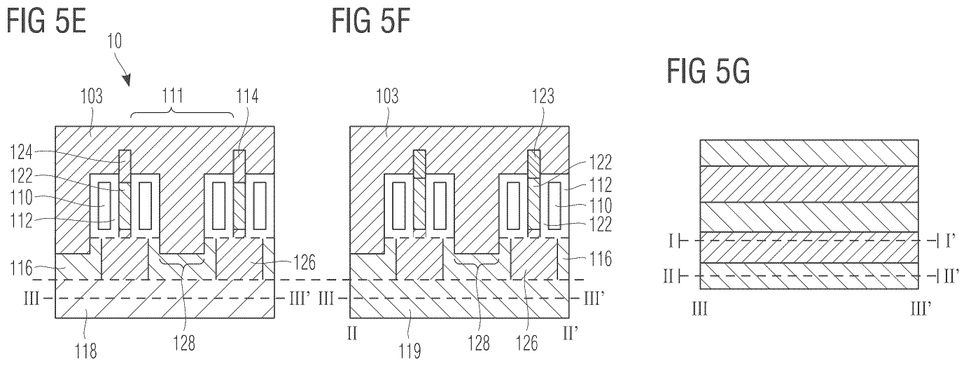

FIGS. 5A to 5G show cross-sectional views of examples of a semiconductor device 10, in which the channel region 122 comprises a doped portion of the second conductivity type and does not comprise a doped portion of the first conductivity type.

FIG. 5A is a horizontal cross-sectional view of the semiconductor device 10. As is shown, gate trenches 111 pattern the semiconductor substrate to ridges 114. Source regions 124 and body contact portions 123 are alternatingly arranged along the first direction. FIG. 5A further shows contact grooves 106 which extend in the first horizontal direction and which are arranged at a central portion of the gate trenches 111. A conductive material is filled in the contact grooves 106 to form groove contacts 128.

FIG. 5B shows a cross-sectional view which is taken between I and I′ so as to intersect portions in which the source region 124 is in electrical contact with the source metallization layer 103. The structure shown in FIG. 5A to 5D refers to a structure in which additionally a contact groove 106 is arranged in the central portion of the gate trench 111 to contact the shielding portion 116. The contact groove 106 extends through the gate electrode 110. Accordingly, the contact groove 106 extends to a deeper depth than according to embodiments, in which the contact is accomplished via a surface of a ridge or a mesa. For example, the contact groove may extend to a deeper depth than the gate trench 111. A conductive material in the contact groove 106 forms a groove contact 128. Accordingly, the gate electrode 110 may be interrupted along the second direction. A source region 124 is arranged in an upper portion of the ridge 114 and is arranged in electrical contact with the source metallization layer 103. Further, a channel region 122 is arranged in the ridge below the source region 124. A current spread region 126 of the first conductivity type is arranged adjacent to the channel region 122. The current spread region 126 does not continuously extend along the second horizontal direction. Shielding portions 116 of the second conductivity type are arranged between adjacent portions of the current spread region 126. The shielding portions 116 are electrically coupled to the source metallization layer 103 via the groove contact 128.

A superjunction structure 117 is arranged below the current spread region 126 and the shielding portions 116. The superjunction structure 117 comprises a first compensation region 118 of the first conductivity type and a second compensation region 119 of the second conductivity type. For example, the first compensation region 118 may be electrically coupled to the current spread region 126. Further, the second compensation region 119 may be electrically coupled to the shielding portion 116. The current spread regions 126 and the first compensation region 118 may be arranged below the ridges. Further, portions of the current spread regions 126 and portions of the shielding portions 116 are arranged below the gate electrode. The current spread region 126 and the shielding portions 116 extend in the first direction. The second compensation region 119 may be arranged below the shielding portion 116 and below the gate trenches 111.

FIG. 5C shows a cross-sectional view which is taken between II and II′ so as to intersect the body contact portions 123. The cross-sectional view of FIG. 5C is similar or identical with the cross-sectional view of FIG. 5B. Differing from the cross-sectional view of FIG. 5B, the body contact portion 123 is in contact with the source metallization layer 103.

FIG. 5D is a horizontal cross-sectional view of the semiconductor device which is taken between III and III′, as is also indicated in FIGS. 5B and 5C so as to intersect the superjunction structure 117. As is shown, the first compensation region 118 and the second compensation region 119 extend in the first horizontal direction. The first compensation region 118 and the second compensation region 119 are alternatingly arranged along the second horizontal direction.

According to further examples, the first and the second compensation regions 118, 119 may extend in the second horizontal direction.

FIG. 5E shows a vertical cross-sectional view of a semiconductor device 10, wherein the arrangement of source region 114, channel region 122, current spread region 126 and shielding portion 116 is similar as illustrated in FIGS. 5A to 5C. The cross-sectional view of FIG. 5E is taken between I and I′, as is also shown in FIG. 5A so as to intersect the source region 124. As is shown, the first compensation region 118 may extend in the second horizontal direction. The first compensation region 118 may be electrically coupled to the current spread region 126.

FIG. 5F shows a vertical cross-sectional view that is taken between II and II′, as is also indicated in FIG. 5A, so as to intersect the body contact portion 123. As is shown, the second compensation region 119 may extend in the second horizontal direction. The second compensation region 119 may be electrically coupled to the shielding portion 116.

FIG. 5G is a horizontal cross-sectional view of the semiconductor device which is taken between III and III′, as is also indicated in FIGS. 5E and 5F so as to intersect the superjunction structure 117. As is shown, the first compensation region 118 and the second compensation region 119 extend in the second horizontal direction. The first compensation region 118 and the second compensation region 119 are alternatingly arranged along the first horizontal direction.

According to FIGS. 5A to 5G, the source region 124 may be contacted via the source metallization 103 from the top of the semiconductor device. The shielding portions 116 and the second compensation region 119 of the second conductivity type are contacted via the groove contact 128. Further, the body contact portion 123 provides an electrical contact between the source terminal and the channel region 122.

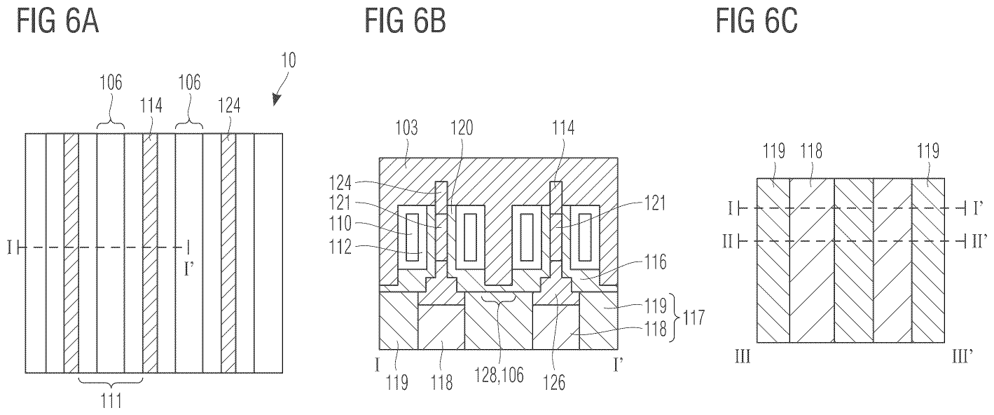

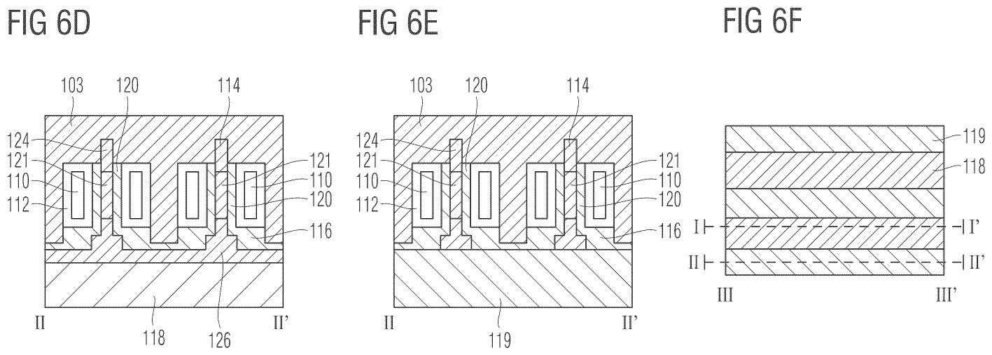

FIG. 6A shows a horizontal cross-sectional view of a semiconductor device 10 in which the channel region 122 comprises a doped portion 120 of the second conductivity type and further a doped portion 121 of the first conductivity type which is arranged in the central portion of the ridge 114. In a similar manner as has been explained with reference to FIG. 5A, gate trenches 111 pattern the semiconductor substrate into ridges 114. Additionally, contact grooves 106 are arranged in a central portion of the gate trenches 111. The contact grooves 106 extend in the first horizontal direction. The source region 124 continuously extends along the first direction.

FIG. 6B is a vertical cross-sectional view which is taken between I and I′. As is seen, a doped portion 121 of the first conductivity type is arranged in the central portion of each of the ridges 114. The doped portion 120 of the second conductivity type is in contact with the shielding portion 116. The first compensation region 118 of the first conductivity type may be electrically coupled to the doped portion 121 of the first conductivity type via the current spread region 126. The gate electrode 110 is arranged adjacent to the channel region 122. The gate electrode 110 is insulated from the channel region 122 by means of a gate dielectric 112. The gate electrode 110 may be divided into two gate electrodes by means of the contact groove 106. For example, a source metallization layer 103 may be arranged in the contact groove 106 to implement a groove contact 128. Due to the groove contact 128, the shielding portion 116 may be electrically coupled to the source terminal.

The semiconductor device illustrated in FIGS. 6A and 6B has a low gate drain capacitance, since the gate is fully embedded into the source metallization layer and the doped portions 120 of the second conductivity type that are electrically coupled to the source terminal 130.

As is further illustrated in FIG. 6B, the doped portion 120 of the second conductivity type is contacted from below by the shielding portion 116. In to this configuration, the shielding portion 116 may be arranged in a self-aligned manner when performing an implantation process into the gate trenches 111.

FIG. 6C is a horizontal cross-sectional view of the semiconductor device so as to intersect the superjunction structure 117. As is shown, the first compensation region 118 and the second compensation region 119 extend in the first horizontal direction. The first compensation region 118 and the second compensation region 119 are alternatingly arranged along the second horizontal direction.

According to further examples, the first and the second compensation regions 118, 119 may extend in the second horizontal direction.

FIG. 6D shows a vertical cross-sectional view of a semiconductor device 10, wherein the arrangement of source region 114, channel region 122, current spread region 126 and shielding portion 116 is similar as illustrated in FIGS. 6A and 6B. The cross-sectional view of FIG. 6D is taken between I and I′, as is also shown in FIG. 6A. As is shown, the first compensation region 118 may extend in the second horizontal direction. The first compensation region 118 may be electrically coupled to the current spread region 126.

FIG. 6E shows a vertical cross-sectional view that is taken between II and II′, as is also indicated in FIG. 6A. As is shown, the second compensation region 119 may extend in the second horizontal direction. The second compensation region 119 may be electrically coupled to the shielding portion 116.

FIG. 6F is a horizontal cross-sectional view of the semiconductor device which is taken so as to intersect the superjunction structure 117. As is shown, the first compensation region 118 and the second compensation region 119 extend in the second horizontal direction. The first compensation region 118 and the second compensation region 119 are alternatingly arranged along the first horizontal direction.

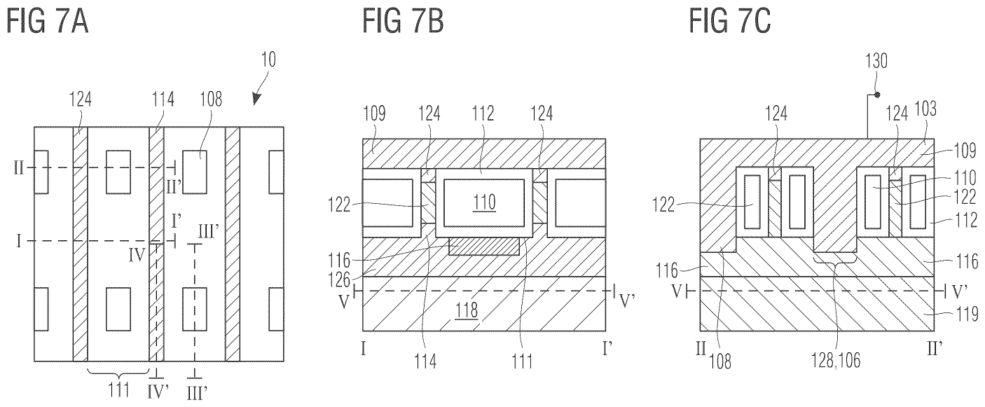

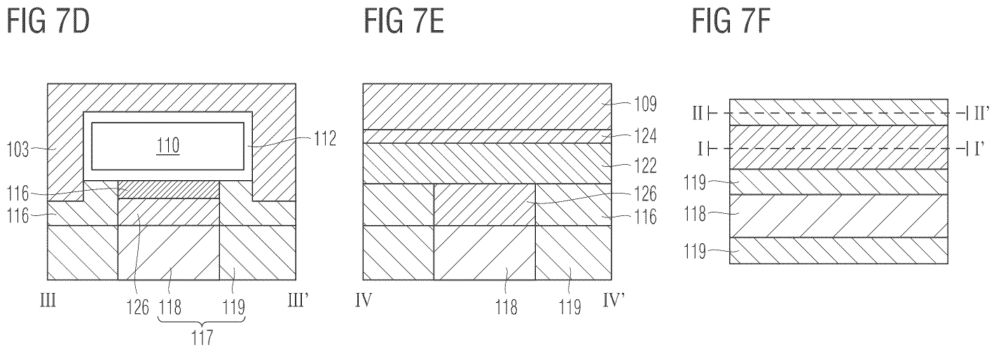

FIG. 7A shows a horizontal cross-sectional view of a semiconductor device 10 according to a further example. The semiconductor device of FIG. 7A is similar to the semiconductor device illustrated in FIG. 5A. Differing from examples illustrated in FIG. 5A, the contact groove 106 and, hence, the groove contact 128 are not implemented so as to continuously extend along the first direction. Instead, the groove contact 128 is implemented as islands or as segments. As is shown in FIG. 7A, the gate trenches 111 pattern the semiconductor substrate into ridges 114. The source region 124 is arranged in the ridges 114 and continuously extends in the first direction. As will be explained below with reference to FIG. 7C, a body contact to the channel region 122 may be implemented via the shielding portions 116. Groove contacts 128 may be arranged as groove contact islands 108 within the gate trenches 111.

FIG. 7B is a cross-sectional view of the semiconductor device between I and I′ in a region where no groove contact islands 108 are present. As is shown in FIG. 7B, the gate trenches 111 pattern the semiconductor substrate 100 into ridges 114. The source region 124 is arranged in an upper portion of the ridges. A channel region 122 of the second conductivity type is arranged adjacent to the source region 124. A current spread region 126 of the first conductivity type is partially arranged within the ridges 114. Optionally, a doped portion of the second conductivity type may be arranged below the gate trenches 111. As a result, the gate-drain capacitance C_{GD} may be decreased and the gate-source capacitance C_{GS} may be increased. Consequently, a risk of a parasitic switch-on may be reduced. The gate electrode 110 is arranged in the gate trenches between adjacent ridges 114. The gate electrode is insulated from the channel region 122 by means of a gate dielectric 112. According to examples, the first compensation region 118 and the second compensation region 119 may extend in the second horizontal direction intersecting the first direction. Accordingly, as is shown in FIG. 7B, the first compensation region 118 of the first conductivity type may be arranged below the current spread region 126.

FIG. 7C shows a cross-sectional view which is taken between II and II′ at a position which intersects the contact groove 128. The cross-sectional view of FIG. 7C further intersects a portion in which a shielding portion 116 of the second conductivity type is arranged below the gate trenches and below the ridges 114. Further, the second compensation region 119 is arranged below the gate trenches. As can be taken from a comparison of FIGS. 7B and 7C, stripes of the current spread region 126 and the shielding portion 116 may be arranged alternatingly along the first direction. The stripes of the current spread region 126 and of the shielding portion 116 extend in the second horizontal direction. In a corresponding manner, the first compensation region 118 and the second compensation region 119 are arranged as stripes extending in the second direction. The first compensation region 118 and the second compensation region 119 are alternatingly arranged along the first horizontal direction. The shielding portions 116 are arranged so as to overlap with the second compensation regions 119. Further, the current spread regions 126 are arranged so as to overlap with the first compensation regions 118.

In the cross-sectional view of FIG. 7C, a groove contact 128 extends to the shielding portion 116. Accordingly, the source metallization layer 103 is in contact with the shielding portion 116. In this manner, the channel region 122 is electrically coupled to the source terminal 130 by means of the shielding portions 116 and the groove contact 128.

FIG. 7D shows a cross-sectional view which is taken between III and III′ along a gate trench 111 including groove contacts 128. As is shown, the first compensation region 118 and the second compensation region 119 are alternatingly arranged along the first direction. Further, the current spread region 126 and the shielding portions 116 are alternatingly arranged along the first direction. The first compensation region 118 and the current spread region 126 are arranged in a portion below the gate electrode 110. The shielding portion 116 and the second compensation region 119 are arranged below the source metallization layer 103.

FIG. 7E shows a cross-sectional view which is taken between IV and IV′ along the first horizontal direction at a position of the source region 124 or a ridge. As is shown, the channel region 122 is continuously arranged below the source region 124. Shielding portions 116 and current spread regions 126 are alternatingly arranged along the first direction.

FIG. 7F is a horizontal cross-sectional view which is taken between V and V′ as indicated in FIGS. 7B and 7C. As is shown, the first compensation region 118 and the second compensation region 119 extend in the second horizontal direction. The first compensation region 118 and the second compensation region 119 are alternatingly arranged along the first horizontal direction.

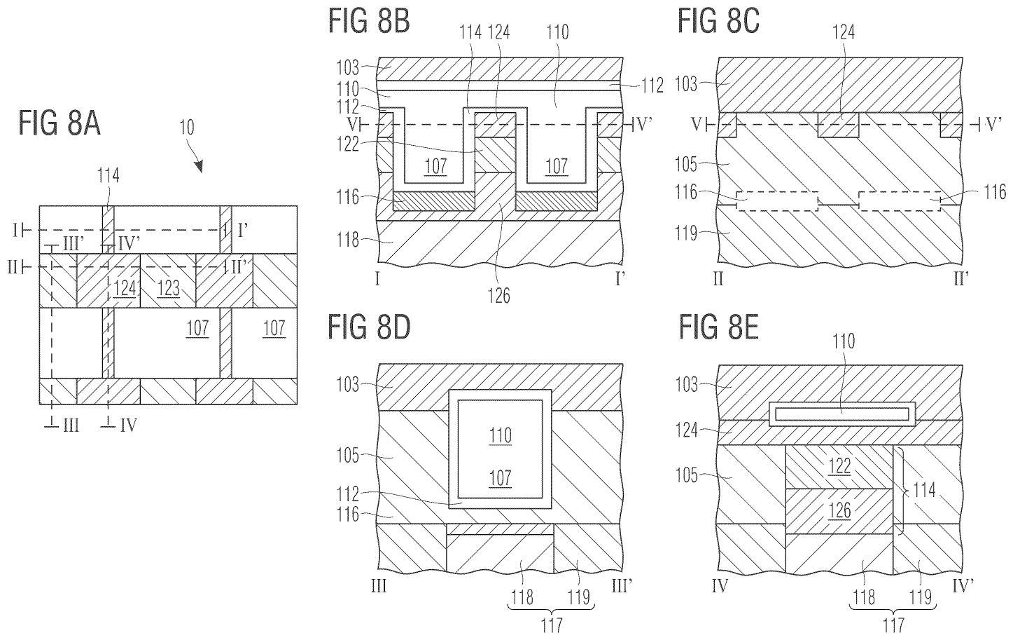

FIG. 8A is a horizontal cross-sectional view of a semiconductor device 10 according to further examples. For example, the cross-sectional view of FIG. 8A may be taken between V and V′ as is indicated in FIGS. 8B and 8C. According to embodiments which are illustrated in FIG. 8A, the gate trenches 111 are formed as segmented trenches. Accordingly, the gate trenches do not continuously extend along the first horizontal direction. Instead, trench segments 107 are formed. For example, a lateral length of the gate trench segments 107 in the first horizontal direction may be less than a width in the second horizontal direction.

As is shown in FIG. 8A, ridges 114 are arranged between adjacent trench segments 107 along a second horizontal direction. Moreover, alternating doped portions of the first and the second conductivity type are formed between adjacent trench segments 107 along the first direction. A gate metal layer portion is formed over the trench segments 107 and extends along the second direction. As will be explained below with reference to FIGS. 8B to 8E, a source metallization layer 103 may be arranged over the entire arrangement. The source metallization layer 103 may be in direct contact with the source regions 124 and the body contact portions 123 between adjacent trench segments 107.

FIG. 8B shows a cross-sectional view of the semiconductor device between I and I′. The cross-sectional view of FIG. 8B is formed to intersect trench segments 107. The cross-sectional view is taken along the second horizontal direction. As is shown, the trench segments 107 pattern the semiconductor substrate into ridges 114. A source region 124 and a channel region 122 and a part of a current spread region 126 are arranged in the ridges 114. A gate electrode 110 is arranged in the trench segments 107. The gate electrode 110 is insulated from the channel region 122 by means of a gate dielectric layer 112. A portion of a conductive material forming the gate electrode 110 is arranged between the source region 124 and the source metallization layer 103. A shielding portion 116 of the second conductivity type is arranged below the trench segments 107. A first compensation region 118 is arranged below the current spread region 126. A portion of the gate dielectric layer 112 may be arranged between the conductive material forming the gate electrode 110 and the source metallization layer 103.

FIG. 8C shows a cross-sectional view which is taken between II and II′ along the second horizontal direction at a position where no trench segment is present. In the cross-section illustrated in FIG. 8C, source regions 124 are arranged alternatingly with body contact portions 123 of the second conductivity type. A doped portion 105 of the second conductivity type is arranged below the source regions 124. The source regions 124 and the body contact portions 123 are in contact with the source metallization layer 103. Shielding portions 116 are indicated by dotted lines. A second compensation region 119 is arranged below the doped portion 105 of the second conductivity type.

FIG. 8D shows a cross-sectional view which is taken between III and III′ along the first horizontal direction. As is shown, the trench segment 107 is arranged in a central portion. The gate electrode 110 is arranged in the trench segment 107 and is insulated from the adjacent semiconductor material by means of a gate dielectric 112. A source metallization layer 103 is arranged over the gate electrode 110. The source metallization layer 103 is insulated from the gate electrode 110. A doped portion 105 of the second conductivity type is arranged laterally adjacent to the gate electrode 110. A shielding portion 116 of the second conductivity type is arranged below the gate electrode 110. A superjunction structure 117 comprising a first compensation region 118 and a second compensation region 119 is arranged below the gate electrode. The first compensation region 118 horizontally overlaps with the gate electrode 110. The second compensation region 119 is arranged laterally adjacent to the gate electrode 110.

FIG. 8E shows a cross-sectional view which is taken between IV and IV′ as is indicated in FIG. 8A. The cross-sectional view is taken along a ridge 114. As is shown, a channel region 122 and a portion of a current spread region 126 are arranged in the ridge 114. The source regions 124 continuously extends along the first horizontal direction. The first compensation region 118 is arranged below the current spread region 126. Moreover, a doped portion 105 of the second conductivity type is arranged adjacent to the ridge 114. Further, the second compensation region 119 is arranged laterally adjacent to the first compensation region 118.

For example, when manufacturing the semiconductor device 10 illustrated in FIGS. 8A to 8E, the shielding portion 116 may be defined via the gate trench 111 using a low-energy implantation process. Further, the doped portion of the channel region 122 may be formed within the ridge 114. As is shown in FIG. 8B, the source region 124 does not contact the source metallization layer 103 at the top of the ridges 114. A contact to the source metallization layer 103 may be accomplished at the gable ends of the ridges 114 as is e.g. illustrated in FIG. 8C. The channel region 122 may be electrically coupled to the source metallization layer 103 via the doped portion 105 of the second conductivity type and the body contact portion 123. The shielding portion 116 may be electrically coupled to the source metallization layer 103 via the doped portion 105 of the second conductivity type as illustrated in FIG. 8C. According to further implementations, different contacting schemes may be employed.

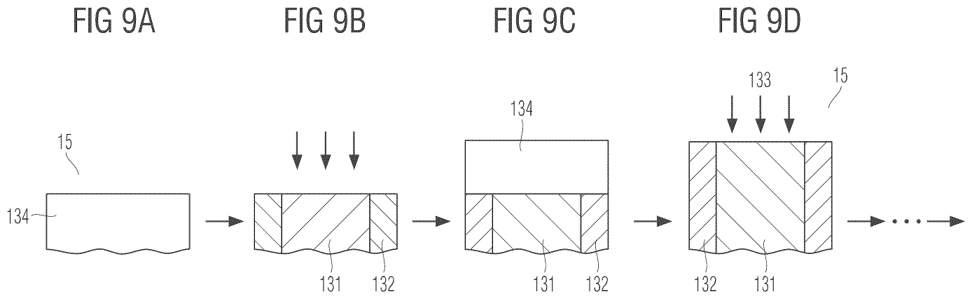

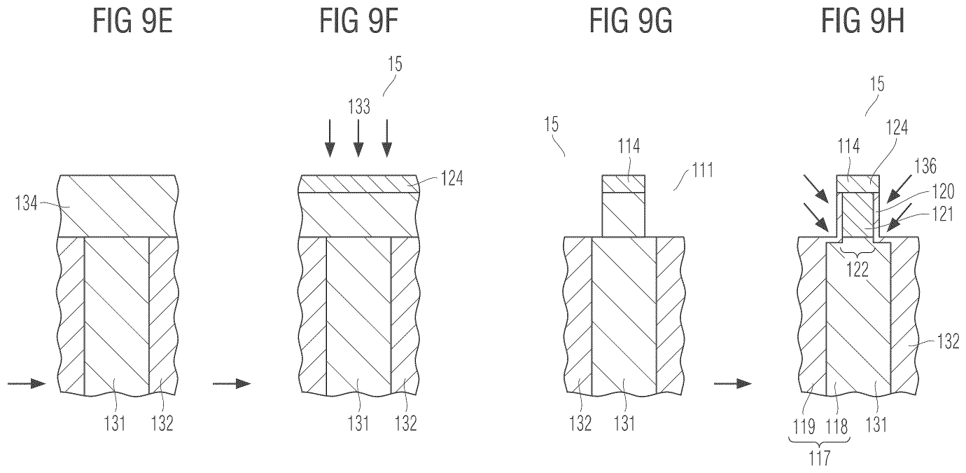

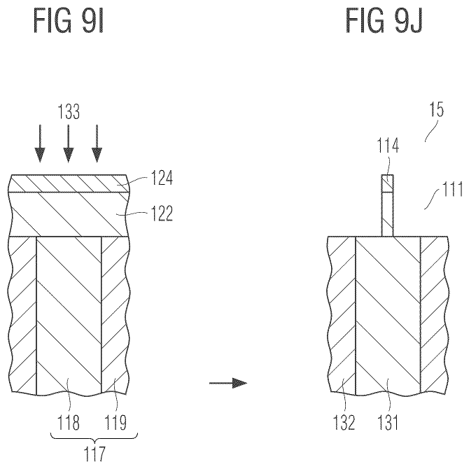

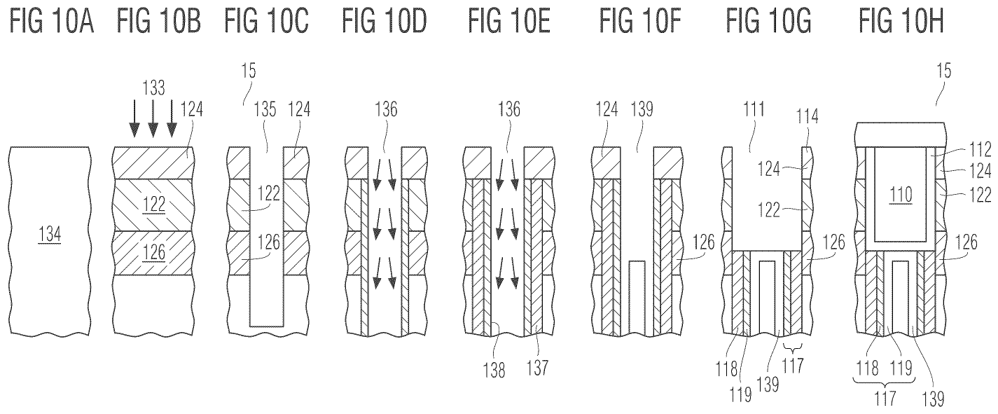

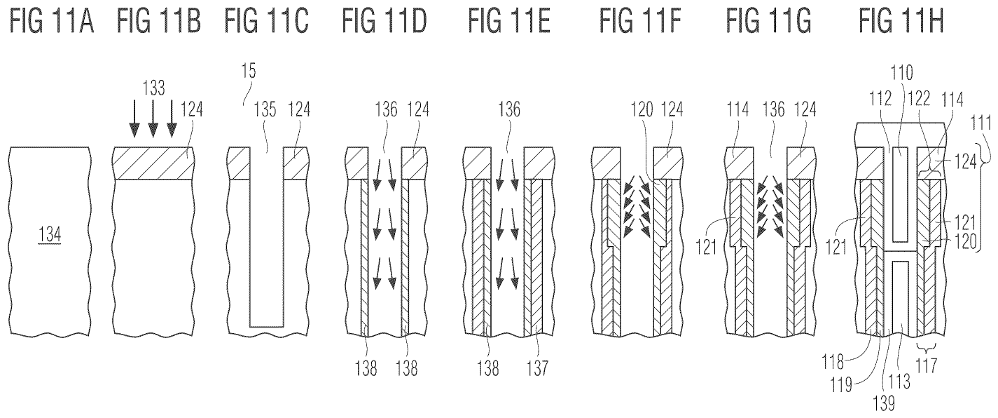

In the following, methods for manufacturing the semiconductor device which has been explained above will be described. FIG. 9A shows an example of a workpiece 15 comprising an epitaxially grown portion 134, e.g. a SiC portion. As is illustrated in FIG. 9B, ion implantation processes 133 may be performed to provide a first doped portion 131 of a first conductivity type and a second doped portion 132 of a second conductivity type. For example, the ion implantation process 133 may be carried out using a doping mask so as to provide the first and the second doped portions 131, 132.

Referring to FIG. 9C, a further epitaxial growth method may be performed to provide a further epitaxially grown portion 134. Then, referring to FIG. 9D, a further ion implantation process 133 may be performed to provide a first doped portion 131 and a second doped portion 132. The sequence described in FIGS. 9C and 9D may be repeated until a desired height of the first and the second doped portions is provided.

FIG. 9E shows a further process of epitaxially growing a semiconductor portion 134. Thereafter, a further implantation process 133 is performed to provide a source region 124 of a first conductivity type adjacent to a first main surface of the workpiece 15. Thereafter, gate trenches 111 are defined in the main surface of a resulting workpiece as is shown in FIG. 9G. For example, the gate trenches 111 may be etched to a bottom portion of the epitaxially grown portion 134 which is arranged over the first doped portion 131 and the second doped portion 132. According to further implementations, the gate trenches 111 may be etched to a smaller depth than the thickness of the epitaxially grown portion 134 so that a part of the epitaxially grown portion 134 is maintained below the gate trenches 111.

Thereafter, as is illustrated in FIG. 9H, a tilted ion implantation process may be performed so as to form the doped portion 120 of second conductivity type and the doped portion 121 of the first conductivity type. During the tilted ion implantation process 136, the implantation angle and the energy may be appropriately set in order to provide the first doped portion 120 and the second doped portion 121. FIG. 9H shows an example of a resulting workpiece 15. Thereafter, further processes for defining elements of the semiconductor device may be performed.

According to an alternative approach, starting from the structure shown in FIG. 9F, further ion implantation process 133 may be performed in order to define the channel region 122, as is illustrated in FIG. 9I. Thereafter, gate trenches 111 may be etched, resulting in a definition of the ridges 114. FIG. 9J shows an example of a resulting workpiece 15. Thereafter, further processes for defining elements of the semiconductor device may be performed.

According to further examples, an epitaxial process may be performed to form an epitaxially grown portion 134, e.g. a SiC body, as is illustrated in FIG. 10A. Thereafter, as is shown in FIG. 10B, various blanket, e.g. unmasked ion implantation processes 133 may be performed so as to define the current spread region 126, the channel region 122, and the source region 124. In particular, various implantation processes of dopants having different conductivity types may be performed.

Thereafter, referring to FIG. 10C, trenches 135 may be etched in the surface of a resulting workpiece. FIG. 10C shows an example of a resulting workpiece 15. Thereafter, tilted ion implantation processes 136 may be performed so as to provide a doped sidewall portion. FIG. 10D shows an example of a workpiece comprising a doped sidewall portion 138 of the second conductivity type.

Thereafter, referring to FIG. 10E, a further implantation process 136 may be performed so as to define the doped sidewall portion 137 of the first conductivity type. According to further examples, the order of the processes may be reversed. Thereafter, a dielectric material 139 is formed, as is illustrated in FIG. 10F. For example, the dielectric material 139 may comprise a silicon oxide. The dielectric material 139 may be formed so as to cover sidewalls of the trench 135. Further, a filling of the dielectric material 139 is formed in an upper trench portion.

Referring to FIG. 10G, a gate trench 111 is etched thereby defining ridges 114. Then, referring to FIG. 10H, a gate dielectric layer 112 is formed adjacent to sidewalls of the gate trench 111. Further, conductive material is filled to form the gate electrode 110. Thereafter, the workpiece 15 may be further processed to provide further components of the semiconductor device.

According to further examples, first, an epitaxially grown portion 134 may be formed as is shown in FIG. 11A. Thereafter, as is shown in FIG. 11B, an ion implantation process 133 may be performed to form the source region 124 of the first conductivity type. Referring to FIG. 11C, trenches 135 may be formed in the workpiece 15. Thereafter, referring to FIG. 11D, a tilted ion implantation process 126 may be performed. As a result, a first doped sidewall portion 138 of the second conductivity type may be formed directly adjacent to the sidewall. Moreover, referring to FIG. 11E, a doped sidewall portion 137 of the first conductivity type may be formed. As is shown in FIG. 11F, thereafter a further tilted ion implantation process 136 may be performed so as to form doped portions of the second conductivity type 120 of the channel region.

Then, as is illustrated in FIG. 11G, a further tilted ion implantation process 136 may be performed so as to form the doped portion 121 of the first conductivity type in a central portion of the ridge 114. Further, as is shown in FIG. 11H, a dielectric material 135 is formed on the sidewall of an extended trench portion 113. Further, a dielectric material 135 for forming the gate dielectric layer 112 is formed in the upper trench portion. Moreover, a conductive material to form the gate electrode 110 is filled in the trenches. The implantation processes illustrated in FIGS. 11D and 11E are performed so that the implanted portions 138, 135 reach down to the bottom of the trench. In the processes described with reference to FIGS. 11F and 11G, the tilt angle is larger than in the processes illustrated in FIGS. 11D and 11E. The tilt angle is adjusted so as to set a desired length of the channel region 122.

While embodiments of the invention have been described above, it is obvious that further embodiments may be implemented. For example, further embodiments may comprise any subcombination of features recited in the claims or any subcombination of elements described in the examples given above. Accordingly, this spirit and scope of the appended claims should not be limited to the description of the embodiments contained herein.

What is claimed is:

1. A semiconductor device comprising a transistor, the transistor comprising:
a plurality of gate trenches formed in a semiconductor substrate, the gate trenches patterning the semiconductor substrate into ridges extending in a first horizontal direction, the ridges being arranged between two adjacent gate trenches, respectively;
a gate electrode arranged in at least one of the gate trenches;
a source region of a first conductivity type electrically coupled to a source terminal;
a channel region comprising a doped portion of a second conductivity type;
a current spread region of the first conductivity type; and
a drain region electrically coupled to a drain terminal,
wherein the source region, the channel region and a part of the current spread region are arranged in the ridges,
wherein the gate electrode is insulated from the channel region and the current spread region,
wherein the source region is arranged at least in a central portion of the ridge,
the semiconductor device further comprising a superjunction structure arranged at a larger distance to the source region than the channel region and comprising:
a first compensation region of the first conductivity type electrically coupled to the drain terminal; and
a second compensation region of the second conductivity type,
wherein the first and the second compensation regions are adjacent to each other,
wherein a doping concentration of the doped portion of the second conductivity type of the channel region decreases in a second horizontal direction intersecting the first horizontal direction from a region close to the gate electrode to the central portion of the ridge.

2. The semiconductor device of claim 1, wherein the channel region further comprises a doped portion of the first conductivity type in the central portion of the ridge.

3. The semiconductor device of claim 2, wherein the first compensation region is electrically coupled to the doped portion of the first conductivity type in the central portion of the ridge.

4. The semiconductor device of claim 1, further comprising a shielding portion of the second conductivity type arranged below the gate trenches, respectively, the shielding portion having a higher doping concentration than the second compensation region, wherein the second compensation region is electrically coupled to the shielding portion.

5. The semiconductor device of claim 1, wherein the superjunction structure extends in the first horizontal direction.

6. The semiconductor device of claim 1, wherein the superjunction structure extends in a second horizontal direction intersecting the first horizontal direction.

7. The semiconductor device of claim 1, wherein the source region continuously extends along the first horizontal direction.

8. The semiconductor device of claim 1, wherein the source region is segmented into source region segments along the first horizontal direction, and wherein the semiconductor device further comprises body contact portions between adjacent source region segments, the body contact portions being electrically coupled to the source terminal.

9. The semiconductor device of claim 1, further comprising a drift region of the first conductivity type arranged between the superjunction structure and the drain region.

10. The semiconductor device of claim 1, wherein the gate trenches continuously extend in the first horizontal direction.

11. The semiconductor device of claim 10, further comprising:
contact grooves running in the first horizontal direction and extending through the gate trenches; and
a metal layer arranged in the contact grooves and electrically coupled to the source terminal and to the second compensation region of the second conductivity type.

12. The semiconductor device of claim 11, wherein the contact grooves continuously extend in the first horizontal direction.

13. The semiconductor device of claim 11, wherein the contact grooves are segmented to groove contact islands.

14. The semiconductor device of claim 1, wherein the gate trenches comprise a plurality of trench segments arranged along the first horizontal direction.

15. The semiconductor device of claim 14, further comprising a metal layer electrically coupled to the source terminal, the metal layer being arranged in contact with the source region between adjacent trench segments and with the doped portion of the second conductivity type of the channel region.

16. A semiconductor device comprising a transistor, the transistor comprising:
a plurality of gate trenches formed in a SiC substrate, the gate trenches patterning the SiC substrate into ridges extending in a first horizontal direction, the ridges being arranged between two adjacent gate trenches, respectively;
a gate electrode arranged in at least one of the gate trenches;
a source region of a first conductivity type electrically coupled to a source terminal;
a channel region comprising a doped portion of a second conductivity type;
a current spread region of the first conductivity type; and
a drain region electrically coupled to a drain terminal,
wherein the source region, the channel region and a part of the current spread region are arranged in the ridges,
wherein the gate electrode is insulated from the channel region and the current spread region,
wherein a width of the source region corresponds to a width of the ridge,
the semiconductor device further comprising a superjunction structure arranged at a larger distance to the source region than the channel region, the superjunction structure comprising:
a first compensation region of the first conductivity type electrically coupled to the drain terminal; and
a second compensation region of the second conductivity type electrically coupled to the doped portion of the second conductivity type of the channel region, the first and the second compensation regions being adjacent to each other.

17. The semiconductor device of claim 16, wherein the first compensation region is electrically coupled to the current spread region.

18. The semiconductor device of claim 16, wherein a doping concentration of the doped portion of the second conductivity type of the channel region decreases in a second horizontal direction intersecting the first horizontal direction from a region close to the gate electrode to a central portion of the ridge.

19. The semiconductor device of claim 18, wherein the channel region further comprises a doped portion of the first conductivity type in the central portion of the ridge.

20. The semiconductor device of claim 19, wherein the first compensation region is electrically coupled to the doped portion of the first conductivity type in the central portion of the ridge.

21. The semiconductor device of claim 16, further comprising:
contact grooves running in the first horizontal direction and extending from a bottom portion of the gate trenches in a depth direction; and
a metal layer arranged in the contact grooves and electrically coupled to the source terminal.

22. The semiconductor device of claim 16, wherein the gate trenches comprise a plurality of trench segments arranged along the first horizontal direction.

23. The semiconductor device of claim 22, further comprising a metal layer electrically coupled to the source terminal, the metal layer being arranged in contact with the source region between adjacent trench segments.
